(19) United States
(12) Patent Application Publication
(10) Pub. No.: US 2026/0190780 A1
(43) Pub. Date: Jul. 2, 2026

(54) DISPLAY APPARATUS

(71) Applicant: LG Display Co., Ltd., Seoul (KR)

(72) Inventor: Jieun KANG, Paju-si (KR)

(73) Assignee: LG Display Co., Ltd., Seoul (KR)

(21) Appl. No.: 19/381,144

(22) Filed: Nov. 6, 2025

(30) Foreign Application Priority Data
Dec. 26, 2024 (KR) 10-2024-0196886

(51) Int. Cl. H10K 59/80; H10K 59/131; H10K 59/40; H10K 102/00

(52) U.S. Cl. CPC H10K 59/873; H10K 59/131; H10K 59/40; H10K 2102/311

(57) ABSTRACT

A display apparatus in some examples can include a substrate, a panel insulating layer disposed on the substrate and having a plurality of insulating layers, a touch pad disposed on the panel insulating layer, a protective layer disposed to be spaced apart from the touch pad on the panel insulating layer and having an organic material, and an over-etched area which is disposed between the touch pad and the protective layer. At least a part of the panel insulating layer is recessed in the over-etched area.

### CROSS-REFERENCE TO RELATED APPLICATION

The present application claims priority to Korean Patent Application No. 10-2024-0196886, filed in the Republic of Korea on December 26, 2024, the entire contents of which is hereby expressly incorporated by reference into the present application.

### BACKGROUND

### Technical Field

The present disclosure relates to a display apparatus.

### Description of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption compared to the LCD apparatus that needs a separate backlight. In addition, there is an advantage in that the OLED display apparatus can drive at a low voltage, have a fast response time, and especially have the inexpensive manufacturing cost.

### SUMMARY OF THE DISCLOSURE

The present disclosure is directed to providing a display apparatus in which it is possible to prevent or minimize a moisture penetration path along which moisture, humidity, etc. can penetrate a pad.

The present disclosure is also directed to providing a display apparatus in which it is possible to prevent or minimize a moisture penetration path of a pad and suppress or prevent or minimize a silver (Ag) residue defect/issue.

The present disclosure is also directed to providing a display apparatus in which a connection line of a pad can be deposited more smoothly.

Objects of the present disclosure are not limited to the above-described objects, and other technical objects can be inferred from the following embodiments.

According to one or more embodiments of the present disclosure, there is provided a display apparatus including a substrate, a panel insulating layer disposed on the substrate and including a plurality of insulating layers, a touch pad disposed on the panel insulating layer, a protective layer disposed to be spaced apart from the touch pad on the panel insulating layer and including an organic material, and an over-etched area which is disposed between the touch pad and the protective layer and in which at least a part of the panel insulating layer is recessed.

According to another embodiment of the present disclosure, there is provided a display apparatus including a substrate, a panel insulating layer disposed on the substrate and including a plurality of insulating layers, a pad disposed on the panel insulating layer, a connection line electrically connected to the pad, and an over-etched area in which at least a part of the panel insulating layer is recessed, wherein the over-etched area overlaps the connection line.

Detailed matters of other embodiments are included in the detailed description and accompanying drawings.

According to the embodiments of the present disclosure, it is possible to prevent or minimize the moisture penetration path along which moisture, humidity, etc. can penetrate the pad.

According to the embodiments of the present disclosure, it is possible to prevent or minimize the moisture penetration path of the pad and suppress or prevent or minimize a silver (Ag) residue defect/issue.

According to the embodiments of the present disclosure, the connection line of the pad can be deposited more smoothly.

According to the embodiments of the present disclosure, it is possible to improve the reliability of the display panel, thereby increasing the life of the display apparatus and also reducing power consumption.

However, effects obtainable from the present disclosure are not limited to the above-described effects, and other effects that are not mentioned will be able to be clearly understood by those skilled in the art to which the present disclosure pertains based on the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one or more embodiments of the present disclosure.

FIG. 2 is a cross-sectional view illustrating a bent state of a display panel according to FIG. 1.

FIG. 3 is a cross-sectional view along line A-A’ in FIG. 1.

FIG. 4 is a specific cross-sectional view of a light-emitting part of FIG. 3.

FIG. 5 is a specific cross-sectional view of a light-emitting part according to a modified example of the present disclosure.

FIG. 6 is a cross-sectional view of a touch part according to FIG. 3.

FIG. 7 is an enlarged view of area Q1 in FIG. 1.

FIG. 8 is a cross-sectional view along line B-B’ in FIG. 7.

FIG. 9 is a cross-sectional view along line C-C’ in FIG. 7.

FIGS. 10 to 12 are views illustrating a manufacturing method for each process operation of the display apparatus according to the embodiments of the present disclosure.

FIG. 13 is a plan view of a display panel according to another embodiment of the present disclosure.

FIG. 14 is a cross-sectional view of a display apparatus according to still another embodiment of the present disclosure.

FIG. 15 is a cross-sectional view of a display apparatus according to yet another embodiment of the present disclosure.

FIG. 16 is a cross-sectional view of a display apparatus according to yet another embodiment of the present disclosure.

### DETAILED DESCRIPTION OF THE EMBODIMENTS

Hereinafter, embodiments will be described with reference to the accompanying drawings. In the specification, when a first component (or an area, a layer, a portion, etc.) is described as “on,” “connected,” or “coupled to” a second component, it means that the first component can be directly connected/coupled to the second component or a third component can be disposed therebetween.

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as first and second can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance. Further, the term “can” fully encompasses all the meanings and coverages of the term “may” and vice versa.

Now, various embodiments of the present disclosure will be described by referring to the figures. All the components of each display apparatus according to all embodiments of the present disclosure are operatively coupled and configured.

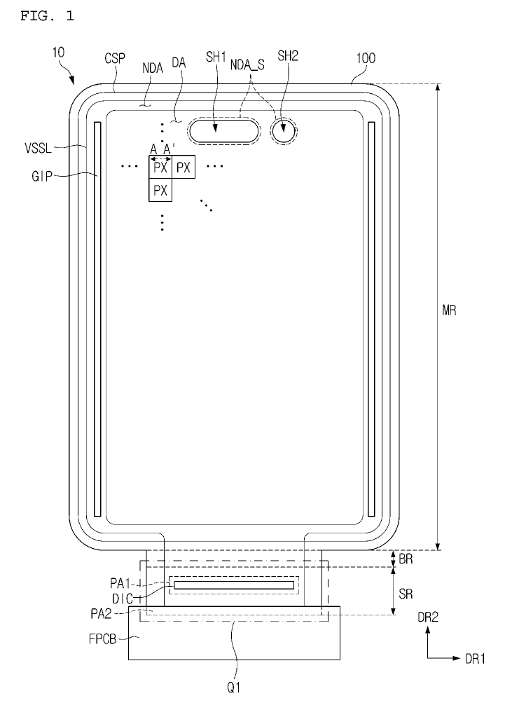

FIG. 1 is a plan view of a display apparatus according to one or more embodiments of the present disclosure.

Referring to FIG. 1, a display apparatus 10 according to one or more embodiments can include a display panel 100. The display panel 100 can include a display area DA including a plurality of pixels PX and a non-display area NDA around the display area DA. The non-display area NDA can surround the display area DA entirely or only in part(s). The flat surface shape of the display area DA can have a rectangular shape. However, the embodiments of the present disclosure are not limited thereto, and the flat surface shape of the display area DA can be a square, circular, elliptical, or other polygonal shapes. For example, the display area DA can have a rectangular shape with rounded corners, but is not limited thereto and can also have a rectangular shape with angled corners.

In embodiments, a first direction DR1 and a second direction DR2 are different directions and intersect each other, for example, directions that intersect vertically in a plan view. In the example of FIG. 1, the first direction DR1 can be generally the same as an extension direction of short sides of the display panel 100, and the second direction DR2 can be the same as an extension direction of long sides of the display panel 100. However, the directions described in the embodiments should be understood as indicating relative directions, and the embodiments are not limited to the described directions.

The display area DA can include short sides extending in the first direction DR1 and long sides extending in the second direction DR2. The non-display area NDA can surround the display area DA. The non-display area NDA can be disposed at one side and the other side of the display area DA in the first direction DR1 and one side and the other side of the display area DA in the second direction DR2.

The display panel 100 can further include a sensor non-display area NDA_S and sensor holes SH1 and SH2 surrounded by the sensor non-display area NDA_S. The sensor hole SH1 and SH2 can be surrounded by the display area DA in a plan view. The sensor hole SH1 and SH2 can be, for example, two sensor holes as in the example of FIG. 1, but the embodiments of the present disclosure are not limited thereto. For example, the sensor hole can be provided as one sensor hole. The two sensor holes SH1 and SH2 can each include a sensor hole in which an infrared sensor is disposed and a sensor hole in which a camera sensor is disposed, but the embodiments of the present disclosure are not limited thereto. The sensor non-display area NDA_S can be disposed between the sensor holes SH1 and SH2 and the display area DA. The sensor non-display area NDA_S can completely surround the sensor holes SH1 and SH2. A pixel PX may not be disposed in the sensor non-display area NDA_S.

A gate driving unit GIP can be disposed in the non-display area NDA located at one side and the other side of the display area DA in the first direction DR1. A low-potential voltage line VSSL can be disposed outside the gate driving unit GIP on the non-display area NDA. For example, in the example of FIG. 1, the low-potential voltage line VSSL can extend from a printed circuit board FPCB, pass a sub-region SR and a bending region BR, can be located outside the gate driving unit GIP on the non-display area NDA, and disposed to surround the display area DA.

The non-display area NDA located at the other side of the display area DA in the second direction DR2 can extend further from a central portion of the other side toward the other side of the display area DA in the second direction DR2. A width of the non-display area NDA in the first direction DR1 further extending from the central portion of the other side toward the other side of the display area DA in the second direction DR2 can be smaller than a width of the non-display area NDA in the first direction DR1 adjacent to the other side of the display area DA in the second direction DR2.

The display apparatus 10 can include a main region MR, the sub-region SR, and the bending region BR between the main region MR and the sub-region SR. The display area DA and the non-display area NDA surrounding four surfaces of the display area DA can form the main region MR, and a portion extending from the central portion of the other side toward the other side of the display area DA in the second direction DR2 can form the bending region BR and the sub-region SR.

The bending region BR can be disposed between the sub-region SR and the main region MR. The sub-region SR can include a first pad area PA1 and a second pad area PA2 located at an end portion of the other side of the sub-region SR in the second direction DR2.

The display apparatus 10 can further include a data driving unit DIC and a printed circuit board FPCB. The data driving unit DIC can be disposed in the first pad area PA1, and the printed circuit board FPCB can be attached to the second pad area PA2. A plurality of pads connected to the data driving unit DIC and the printed circuit board FPCB can be disposed in each of the first pad area PA1 and the second pad area PA2.

The data driving unit DIC can be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the present disclosure are not limited thereto, and the data driving unit DIC can be disposed by a chip on glass or chip on film method.

The display panel 100 according to one embodiment can further include a crack sensing pattern CSP surrounding the low-potential voltage line VSSL. The crack sensing pattern CSP can be disposed to completely surround the display area DA as illustrated in FIG. 1. For example, the crack sensing pattern CSP can be disposed outside the low-potential voltage line VSSL. However, the embodiments of the present disclosure are not limited thereto, and a part of the crack sensing pattern CSP may not be disposed in the non-display area NDA of the other side of the display area DA in the second direction DR2.

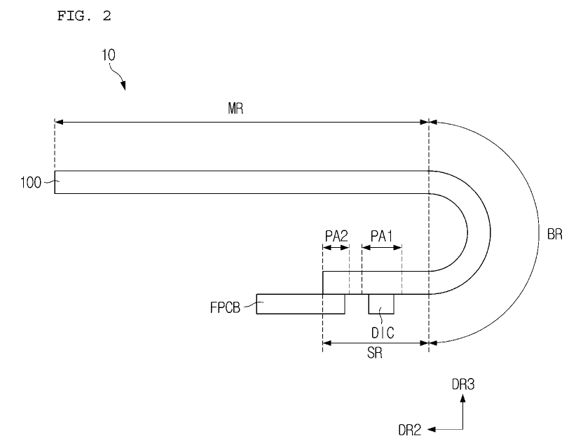

FIG. 2 is a cross-sectional view illustrating a bent state of a display panel according to FIG. 1.

Referring to FIG. 2, the bending region BR of the display panel 100 of the display apparatus 10 according to one embodiment can be bent in a thickness direction (or a third direction DR3). Accordingly, the main region MR and the sub-region SR can overlap each other in the thickness direction. The display panel 100 can be bent in such a manner that a lower surface of the main region MR faces an upper surface of the sub-region SR. The printed circuit board FPCB can be attached to an end portion of the sub-region SR.

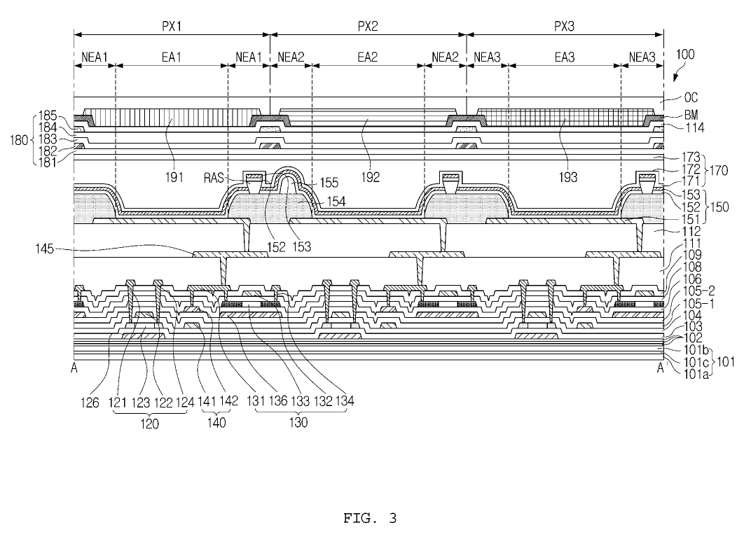

FIG. 3 is a cross-sectional view along line A-A’ in FIG. 1.

Referring to FIG. 3, the pixel PX (e.g., see FIG. 1) of the display panel 100 can include a plurality of sub-pixels PX1, PX2, and PX3. A first sub-pixel PX1 can be a red sub-pixel, a second sub-pixel PX2 can be a green sub-pixel, and a third sub pixel PX3 can be a blue sub-pixel, but the embodiments of the present disclosure are not limited thereto. In some embodiments, the pixel PX further includes a fourth sub-pixel, and the fourth sub-pixel can be a white sub-pixel, but the embodiments of the present disclosure are not limited thereto. In some embodiments, the pixel can include one red sub-pixel, two green sub-pixels, and one blue sub-pixel, but the embodiments of the present disclosure are not limited thereto. For example, the plurality of sub-pixels PX1, PX2, and PX3 can be arranged in a stripe manner in the first direction DR1, but are not limited thereto, and can be arranged in a pentile manner.

The display panel 100 can include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 can include at least one panel insulating layer and at least one touch insulating layer between the substrate 101 and the light-emitting part 150. The at least one panel insulating layer can include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer can include at least one of a touch buffer layer 181, a first touch insulating layer 183, and a second touch insulating layer 184.

The substrate 101 can include one or more plastic materials. For example, the substrate 101 can be a multi-substrate including a plurality of plastic materials, such as polyimide, etc. For example, the substrate 101 can include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

A buffer layer 102 can be disposed on the substrate 101. The buffer layer 102 can minimize or delay the diffusion of moisture or oxygen penetrating the substrate 101. The buffer layer 102 can be formed by alternately stacking silicon nitride (SiNₓ) and silicon oxide (SiOₓ) at least once, but the embodiments of the present disclosure are not limited thereto.

A first light-blocking layer 126 can be disposed on the buffer layer 102. The first light-blocking layer 126 can prevent light from transmitting a first semiconductor layer 123 of the first thin film transistor 120. For example, the first semiconductor layer 123 can be disposed to overlap the first light-blocking layer 126. The first light-blocking layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 can be disposed on the buffer layer 102 and the first light-blocking layer 126. The first insulating layer 103 can prevent a short circuit between a component of the first thin film transistor 120 and the first light-blocking layer 126. The first insulating layer 103 can be formed of the same material as the buffer layer 102, but the embodiments of the present disclosure are not limited thereto. For example, the first insulating layer 103 can be formed of an inorganic insulation material, such as silicon nitride (SiNₓ) or silicon oxide (SiO ₓ), but the embodiments of the present disclosure are not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 can be disposed on the first insulating layer 103. The first semiconductor layer 123 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 can include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor can be formed of the polycrystalline semiconductor layer.

The second insulating layer 104 can be disposed on the first semiconductor layer 123. The second insulating layer 104 can be formed of the same material as the first insulating layer 103 and can prevent a short circuit between the first semiconductor layer 123 and another component of the first thin film transistor 120.

The first gate electrode 122 can be disposed on the second insulating layer 104. The first gate electrode 122 can be disposed on the second insulating layer 104 to overlap the channel area of the first semiconductor layer 123. The first gate electrode 122 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 can be disposed along with a gate line.

The third insulating layers 105-1 and 105-2 can be disposed on the first gate electrode 122. The third insulating layers 105-1 and 105-2 can be formed by alternately stacking silicon nitride (SiNₓ) and silicon oxide (SiOₓ) at least once, but the embodiments of the present disclosure are not limited thereto. For example, the 3-1 insulating layer 105-1 can include silicon oxide (SiOₓ), and the 3-2 insulating layer 105-2 can include silicon nitride (SiNₓ), but the embodiments of the present disclosure are not limited thereto.

The first source electrode 121 and the first drain electrode 124 can be disposed on the third insulating layers 105-1 and 105-2.

The first source electrode 121 and the first drain electrode 124 can be electrically connected to the first semiconductor layer 123 through contact holes. The first source electrode 121 and the first drain electrode 124 can include a metallic material. For example, the first source electrode 121 and the first drain electrode 124 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 can be disposed along with a data line. For example, the data line can be made of the same material as the first source electrode 121 and the first drain electrode 124 and can be formed coplanarly therewith, but the embodiments of the present disclosure are not limited thereto.

A storage electrode 140 can be disposed to be spaced apart from the first thin film transistor 120. The storage electrode 140 can include a first storage electrode 141 and a second storage electrode 142.

The first storage electrode 141 can be formed of the same material as the first gate electrode 122 and disposed on the same layer as the first gate electrode 122, but the embodiments of the present disclosure are not limited thereto.

The second storage electrode 142 can be disposed on the first storage electrode 141. The second storage electrode 142 can be disposed on the third insulating layers 105-1 and 105-2, and the third insulating layers 105-1 and 105-2 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

The second thin film transistor 130 can be disposed to be spaced apart from the first thin film transistor 120 and the storage electrode 140. The second thin film transistor 130 can include a second source electrode 131, a second gate electrode 132, a second semiconductor layer 133, and a second drain electrode 134.

A second light-blocking layer 136 can be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 can be disposed to overlap the second light-blocking layer 136.

The fourth insulating layer 106 can be disposed on the second light-blocking layer 136. The fourth insulating layer 106 can be formed of the same material as the first insulating layer 103, the second insulating layer 104, or the third insulating layers 105-1 and 105-2, but the embodiments of the present disclosure are not limited thereto.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 can be disposed on the second semiconductor layer 133. The fifth insulating layer 108 can be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 can be disposed on the fifth insulating layer 108.

The second gate electrode 132 can be formed of the same material as the first gate electrode 122. For example, the second gate electrode 132 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 can be disposed on the second gate electrode 132. The sixth insulating layer 109 can be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 can be disposed on the sixth insulating layer 109.

The second source electrode 131 and the second drain electrode 134 can be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 can be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 can be electrically connected to the second storage electrode 142. The second source electrode 131 can pass through the sixth insulating layer 109, the fifth insulating layer 108, and the fourth insulating layer 106 and can be electrically connected to the second storage electrode 142.

The first thin film transistor 120 can be a driving transistor, and the second thin film transistor 130 can be a switching transistor, but the embodiments of the present disclosure are not limited thereto.

A first protective layer 111 can be disposed on the first source electrode 121 and the first drain electrode 124.

The first protective layer 111 can planarize an upper portion of the first thin film transistor 120 and protect the first thin film transistor 120. The first protective layer 111 can be formed of an organic material. For example, the first protective layer 111 can be formed of an organic material including an acrylic resin, an epoxy resin, a phenolic resin, a polyamide resin, or a polyimide resin, but the embodiments of the present disclosure are not limited thereto.

The second protective layer 112 can be disposed on the first protective layer 111. The second protective layer 112 can include the same material as the first protective layer 111, but the embodiments of the present disclosure are not limited thereto.

In some embodiments, a third protective layer can be further disposed on an upper surface of the second protective layer 112, but the embodiments of the present disclosure are not limited thereto.

A connection electrode 145 can be disposed between the first protective layer 111 and the second protective layer 112.

The connection electrode 145 can electrically connect the first thin film transistor 120 to the light-emitting part 150. The connection electrode 145 can be formed of the same material as the first source electrode 121 and the first drain electrode 124, but the embodiments of the present disclosure are not limited thereto.

The connection electrode 145 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include a first electrode 151, an organic layer 152, and a second electrode 153. The first electrode 151 can serve as an anode, and the second electrode 153 can serve as a cathode.

The first electrode 151 can be disposed on the second protective layer 112. The first electrode 151 can be electrically connected to the first thin film transistor 120 through a contact hole formed in the second protective layer 112. The first electrode 151 can be a reflective electrode that reflects light, but the embodiments of the present disclosure are not limited thereto. The first electrode 151 can include a metallic material with high reflectance, such as a stacked structure (Ti/Al/Ti) of aluminum (Al) and titanium (Ti), a stacked structure (ITO/Al/ITO) of aluminum (Al) and indium tin oxide (ITO), or an APC alloy and can be formed of a single layer or multiple layers, but the embodiments of the present disclosure are not limited thereto.

The organic layer 152 can be disposed on the first electrode 151. The organic layer 152 can include one or more light-emitting structures (or light-emitting elements or elements) stacked on the first electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. The organic layer 152 can be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure can include an organic light-emitting layer. The organic layer 152 can include a red light-emitting layer, a green light-emitting layer, and a blue light-emitting layer. The organic layer 152 can be a white light-emitting layer, but the embodiments of the present disclosure are not limited thereto. Hereinafter, a specific structure of the organic layer 152 according to one or more embodiments of the present disclosure will be described.

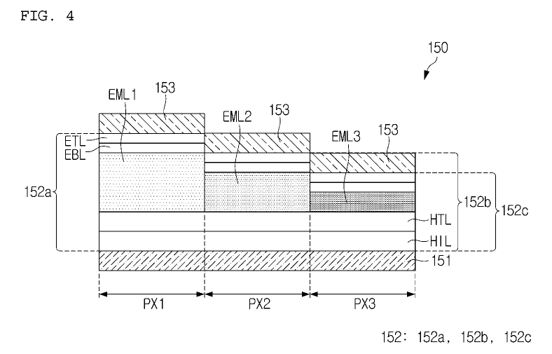

FIG. 4 is a specific cross-sectional view of a light-emitting part of FIG. 3.

Referring to FIG. 4, the light-emitting part 150 can include the first sub-pixel PX1, the second sub-pixel PX2, and the third sub-pixel PX3.

A thickness of the light-emitting part 150 in each sub-pixel PX1, PX2, or PX3 can be different, but the embodiments of the present disclosure are not limited thereto, and the thickness of the light-emitting part 150 in each sub-pixel PX1, PX2, or PX3 can be the same.

The organic layer 152 can include a first organic layer 152a disposed in the first sub-pixel PX1, a second organic layer 152b disposed in the second sub-pixel PX2, and a third organic layer 152c disposed in the third sub-pixel PX3. Light-emitting layers EML1, EML2, and EML3 of the organic layers 152a, 152b, and 152c can be physically separated, but lower layers and upper layers of the light-emitting layers EML1, EML2, and EML3 can be formed integrally across the sub-pixels PX1, PX2, and PX3. A thicknesses of each light-emitting layer EML1, EML2, or EML3 can be different. For example, a thickness of a first light-emitting layer EML1 can be the greatest, a thickness of a second light-emitting layer EML2 can be the second greatest, and a thickness of the third light-emitting layer EML3 can be the smallest, but the embodiments of the present disclosure are not limited thereto.

A hole injecting layer HIL can be disposed on the first electrode 151. The hole injecting layer HIL can be located between the first electrode 151 and the light-emitting layers EML1, EML2, and EML3. The hole injecting layer HIL can be disposed integrally across the sub-pixels PX1, PX2, and PX3, but is not limited thereto.

A hole transporting layer HTL can be disposed on the hole injecting layer HIL. The hole transporting layer HTL can be located between the hole injecting layer HIL and the light-emitting layers EML1, EML2, and EML3. The hole transporting layer HTL can be disposed integrally across the sub-pixels PX1, PX2, and PX3, but is not limited thereto.

The light-emitting layers EML1, EML2, and EML3 can be disposed on the hole transporting layer HTL. The first light-emitting layer EML1 can be disposed in the first sub-pixel PX1, the second light-emitting layer EML2 can be disposed in the second sub-pixel PX2, and the third light-emitting layer EML3 can be disposed in the third sub-pixel PX3.

A thicknesses of each light-emitting layer EML1, EML2, or EML3 can be different, but is not limited thereto.

Each of the first light-emitting layer EML1, the second light-emitting layer EML2, and the third light-emitting layer EML3 can include a material that can emit light in the visible light range by receiving and combining holes and electrons.

An electron blocking layer EBL can be disposed on each light-emitting layer EML1, EML2, or EML3. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3, but is not limited thereto.

The second electrode 153 can be disposed on the electron transporting layer ETL.

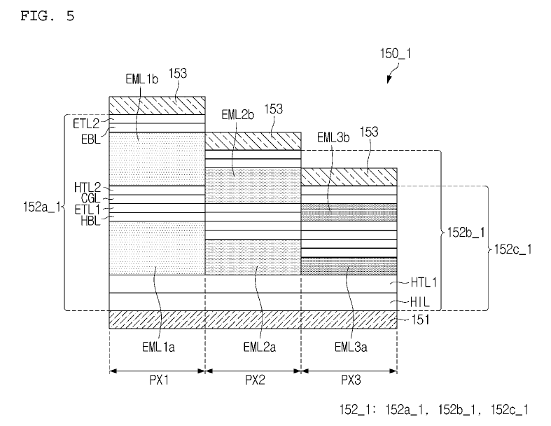

FIG. 5 is a specific cross-sectional view of a light-emitting part according to a modified example.

Referring to FIGS. 4 and 5, an organic layer 152_1 can include a first organic layer 152a_1 disposed in the first sub-pixel PX1, a second organic layer 152b_1 disposed in the second sub-pixel PX2, and a third organic layer 152c_1 disposed in the third sub-pixel PX3.

An example in which the light-emitting layer is formed in 1 stack or 2 stacks for each sub-pixel PX1, PX2, or PX3 of the organic layers 152 and 152_1 is illustrated, but the embodiments of the present disclosure are not limited thereto, and the light-emitting layer can be formed in 3 or more stacks.

The light-emitting layers of each organic layer 152a_1, 152b_1, or 152c_1 can be physically separated, but the lower layers and upper layers of the light-emitting layers can be disposed integrally across the sub-pixels PX1, PX2, and PX3. The thickness of each light-emitting layer can be different.

On the first electrode 151, the hole injecting layer HIL, a first hole transporting layer HTL1, light-emitting layers EML1a, EML2a, and EML3a, a hole blocking layer HBL, a first electron transporting layer ETL1, a common charge layer CGL, a second hole transporting layer HTL2, light-emitting layers EML1b, EML2b, and EML3b, an electron blocking layer EBL, and a second electron transporting layer ETL2 can be sequentially disposed.

The hole blocking layer HBL can be disposed integrally across the sub-pixels PX1, PX2, and PX3.

The common charge layer CGL can be disposed between the first electron transporting layer ETL1 and the second hole transporting layer HTL2. The common charge layer CGL can include a conductive material, but the embodiments of the present disclosure are not limited thereto.

The contents that are substantially the same as those of the hole injecting layer HIL, the hole transporting layer HTL, the light-emitting layers EML1, EML2, and EML3, the electron transporting layer ETL, and the electron blocking layer EBL described in FIG. 4 can be applied to the hole injecting layer HIL, the first hole transporting layer HTL1, the light-emitting layers EML1a, EML2a, and EML3a, the first electron transporting layer ETL1, the second hole transporting layer HTL2, the light-emitting layers EML1b, EML2b, and EML3b, the electron blocking layer EBL, and the second electron transporting layer ETL2.

The second electrode 153 can be disposed on the second electron transporting layer ETL2.

Referring back to FIG. 3, the second electrode 153 can be disposed on the organic layer 152. The second electrode 153 can be a transparent electrode that transmits light, but the embodiments of the present disclosure are not limited thereto. For example, the second electrode 153 can include a transparent conductive material, such as indium tin oxide (ITO) or indium zinc oxide (IZO), or a metal that transmits visible light, but the embodiments of the present disclosure are not limited thereto.

A bank 154 can be disposed to expose the first electrode 151. The bank 154 can define openings (or light-emitting areas EA1, EA2, and EA3) of the sub-pixels PX1, PX2, and PX3 and can be disposed to cover an edge portion (or a periphery) of the

first electrode 151. For example, the first sub-pixel PX1 can include a first light-emitting area EA1 and a first non-light-emitting area NEA1 around the first light-emitting area EA1, the second sub-pixel PX2 can include a second light-emitting area EA2 and a second non-light-emitting area NEA2 around the second light-emitting area EA2, and the third sub-pixel PX3 can include a third light-emitting area EA3 and a third non-light-emitting area NEA3 around the third light-emitting area EA3. For example, each non-light-emitting area NEA1, NEA2, or NEA3 can correspond to a boundary between adjacent sub-pixels PX1, PX2, and PX3.

The bank 154 can include a black-based material. For example, the bank 154 can be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 can be an opaque bank. When the bank 154 is formed of a material containing black pigment or black dye, it is possible to block external light or light reflected from the outside, thereby preventing a reduction in the luminance of the display apparatus.

A barrier RAS can be further disposed on the bank 154. As illustrated in FIG. 3, the barrier RAS can be disposed at all the boundaries NEA1, NEA2, and NEA3 between the sub-pixels PX1, PX2, and PX3, but the embodiments of the present disclosure are not limited thereto. The barrier RAS can be disposed directly on an upper surface of the bank 154, but the embodiments of the present disclosure are not limited thereto. The barrier RAS can serve to separate the organic layer 152 from the boundaries of adjacent sub-pixels PX1, PX2, and PX3. In some embodiments, the barrier RAS can be omitted, and a trench structure recessed from the surface of the bank 154 can be applied.

A spacer 155 can be further disposed on the bank 154. The spacer 155 can be formed of the same material as the bank 154, but the embodiments of the present disclosure are not limited thereto. For example, the spacer 155 can be a transparent bank, but is not limited thereto, and the spacer 155 can be formed of the same material as the bank 154. For example, the spacer 155 can be disposed on at least one of the boundaries of the first to third sub-pixels PX1, PX2, and PX3, but the embodiments of the present disclosure are not limited thereto. The bank 154 and the spacer 155 can be formed of the same material and formed simultaneously through a halftone mask, but the embodiments of the present disclosure are not limited thereto.

The organic layer 152 can be disposed on the first electrode 151, the bank 154, and the spacer 155. The second electrode 153 can be disposed on the organic layer 152.

The encapsulation part 170 can be disposed on the second electrode 153. The encapsulation part 170 can include one or more insulating layers. For example, the encapsulation part 170 can include a first encapsulation layer 171, a second encapsulation layer 172 disposed on the first encapsulation layer 171, and a third encapsulation layer 173 disposed on the second encapsulation layer 172. The encapsulation part 170 can include one or more inorganic insulation material layers and one or more organic material layers. For example, the first encapsulation layer 171 and the third encapsulation layer 173 can include an inorganic insulation material, and the second encapsulation layer 172 can include an organic material, but the embodiments of the present disclosure are not limited thereto.

The touch part 180 can be disposed on the encapsulation part 170. The touch part 180 can include the touch buffer layer 181, a first touch conductive layer, the first touch insulating layer 183, the second touch insulating layer 184, and a second touch conductive layer. In some embodiments, one or more touch organic layers can be further disposed on the second touch conductive layer, but the embodiments of the present disclosure are not limited thereto.

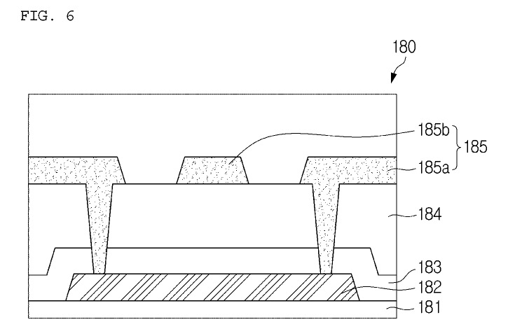

FIG. 6 is a cross-sectional view of a touch part according to FIG. 3.

Referring to FIGS. 3 and 6, the touch buffer layer 181 can be disposed on the encapsulation part 170. For example, a touch buffer layer 181 can be disposed on the third encapsulation layer 173. The touch buffer layer 181 can be formed of the same material as the buffer layer 102, but the embodiments of the present disclosure are not limited thereto.

The first touch conductive layer can be disposed on the touch buffer layer 181. The first touch conductive layer can include a bridge electrode 182. The bridge electrode 182 and a sensor electrode 185 to be described below can be disposed at each of the boundaries between adjacent sub-pixels PX1, PX2, and PX3. For example, the bridge electrode 182 and the sensor electrode 185 can be disposed in the non-light-emitting areas NEA1, NEA2, and NEA3. The bridge electrode 182 and the sensor electrode 185 can overlap the black matrix BM to be described below in the thickness direction. The black matrix BM can cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 can be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 can be formed of silicon oxide (SiOₓ), silicon nitride (SiNₓ), or multiple layers thereof, but the embodiments of the present disclosure are not limited thereto. The second touch insulating layer 184 can include an organic insulation material, but the embodiments of the present disclosure are not limited thereto, and the second touch insulating layer 184 can include the same material as the first touch insulating layer 183.

The second touch conductive layer can be disposed on the second touch insulating layer 184. The second touch conductive layer can include a first sensor electrode 185a and a second sensor electrode 185b. The sensor electrode 185 can include the first sensor electrode 185a extending in the first direction DR1 (see FIG. 1) and the second sensor electrode 185b extending in the second direction DR2 (see FIG. 1) different from the first direction DR1.

The bridge electrode 182 can be electrically connected to the first sensor electrode 185a through a contact hole formed in the first touch insulating layer 183 and the second touch insulating layer 184. For example, the first sensor electrode 185a and the bridge electrode 182 can extend in the first direction DR1 (see FIG. 1).

The sensor electrode 185 and the bridge electrode 182 can include a metallic material. For example, the sensor electrode 185 and the bridge electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

Referring back to FIG. 3, the filter insulating layer 114 can be disposed on the second touch conductive layer. The filter insulating layer 114 can be formed of an inorganic insulation material, such as silicon nitride (SiNₓ) or silicon oxide (SiOₓ), but the embodiments of the present disclosure are not limited thereto.

The black matrix BM can be disposed on the filter insulating layer 114. The black matrix BM can include a black-based material. For example, the black matrix BM can include a light-blocking material or a light-absorbing material. For example, the black matrix BM can be formed of a material including a black pigment, a black dye, etc. The black matrix BM can cover the bridge electrode 182 and the sensor electrode 185. Accordingly, the bridge electrode 182 and the sensor electrode 185 can be prevented from being visible from the outside. For example, a width of the black matrix BM can be smaller than a width of the bank 154.

For example, spacing distances between the boundaries between the light-emitting areas EA1, EA2, and EA3 and the non-light-emitting areas NEA1, NEA2, and NEA3 and an end of the black matrix BM can be longer than spacing distances between the boundaries between the light-emitting areas EA1, EA2, and EA3 and the non-light-emitting areas NEA1, NEA2, and NEA3 and an end of the bank 154. The end of the bank 154 can be aligned with the boundaries between the light-emitting areas EA1, EA2, and EA3 and the non-light-emitting areas NEA1, NEA2, and NEA3, but the embodiments of the present disclosure are not limited thereto. In the display panel 100 according to one embodiment, since the bank 154 can include a black-based material and the spacing distances between the end of the black matrix BM and the boundaries between the light-emitting areas EA1, EA2, and EA3 and the non-light-emitting areas NEA1, NEA2, and NEA3 can be longer than the spacing distances between the end of the bank 154 and the boundaries between the light-emitting areas EA1, EA2, and EA3 and the non-light-emitting areas NEA1, NEA2, and NEA3, light emitted from the light-emitting areas EA1, EA2, and EA3 can be emitted upward with a wider viewing angle as much as the spacing spaces between the end of the black matrix BM and the boundaries between the light-emitting areas EA1, EA2, and EA3 and the non-light-emitting areas NEA1, NEA2, and NEA3. Accordingly, it is possible to prevent a reduction in luminance according to a viewing angle. However, when the spacing distances between the end of the black matrix BM and the boundaries between the light-emitting areas EA1, EA2, and EA3 and the non-light-emitting areas NEA1, NEA2, and NEA3 can be longer than the spacing distances between the end of the bank 154 and the boundaries between the light-emitting areas EA1, EA2, and EA3 and the non-light-emitting areas NEA1, NEA2, and NEA3 and the bank 154 is formed of only a transparent material, externally incident light can be reflected by the bank 154, resulting in visible ring-shaped spots. However, in the display panel 100 according to one embodiment, the externally incident light can be absorbed or blocked by the bank 154 including a black-based material, thereby preventing the occurrence of the ring-shaped spots.

The color filters 191, 192, and 193 can be disposed on the black matrix BM. The color filters 191, 192, and 193 can be disposed on the first to third sub-pixels PX1, PX2, and PX3, respectively, and can block specific colors from light emitted from the light-emitting area EA1, EA2, and EA3 of the sub-pixels PX1, PX2, and PX3. A first color filter 191 can be provided to block light of other colors not including red (R) light. In this case, the first color filter 191 can be provided as a red color filter. The second color filter 192 can be provided to block light of other colors not including green (G) light. In this case, a second color filter 192 can be provided as a green color filter. A third color filter 193 provided in the third sub-pixel PX3 can be provided to block light of other colors not including blue (B) light. In this case, the third color filter 193 can be provided as a blue color filter. However, the embodiments of the present disclosure are not limited thereto.

For example, each color filter 191, 192, or 193 can come into direct contact with side and upper surfaces of the black matrix BM. For example, each color filter 191, 192, or 193 can be spaced apart from the boundaries of adjacent sub-pixels PX1, PX2, and PX3, but the embodiments of the present disclosure are not limited thereto, and the color filters 191, 192, and 193 can overlap each other in the thickness direction.

The planarization layer OC can be disposed on the color filters 191, 192, and 193. The planarization layer OC can serve to planarize a step formed by the color filters 191, 192, and 193. For example, the planarization layer OC can include an organic insulation material.

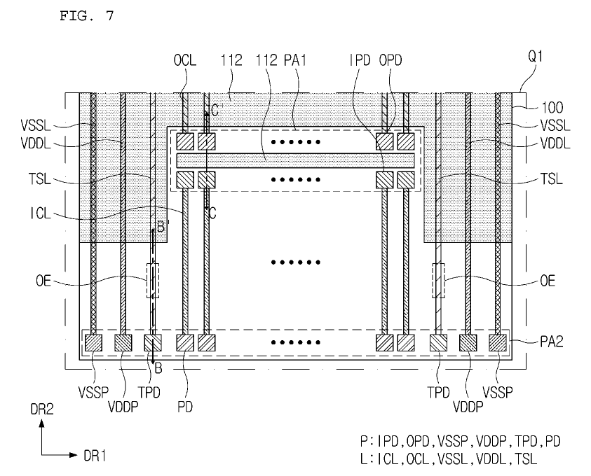

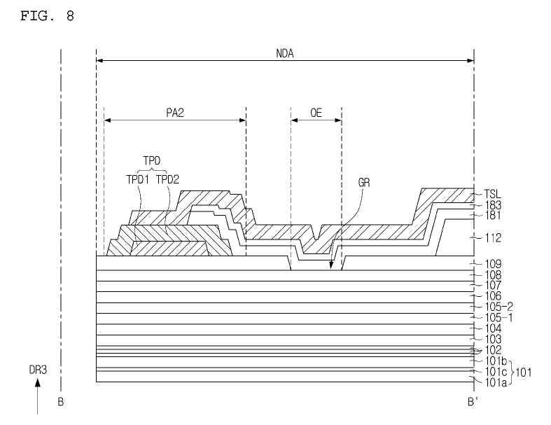

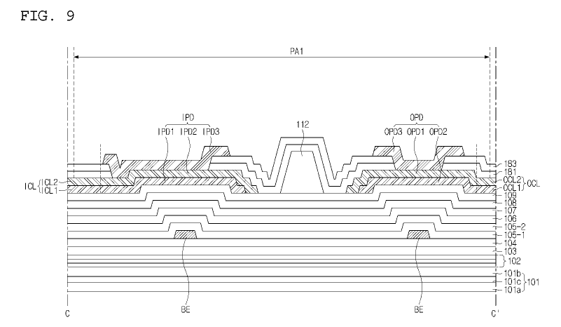

FIG. 7 is an enlarged view of area Q1 in FIG. 1. FIG. 8 is a cross-sectional view along line B-B’ in FIG. 7. FIG. 9 is a cross-sectional view along line C-C’ in FIG. 7.

For convenience of description, FIG. 7 illustrates the display panel 100 from which the data driving unit DIC and the printed circuit board FPCB are omitted.

Referring to FIGS. 1 and 7 to 9, the display apparatus 10 can include a plurality of pads P (IPD, OPD, VSSP, VDDP, TPD, and PD) and a plurality of connection lines L (ICL, OCL, VSSL, VDDL, and TSL).

The first pad area PA1 can include an input pad IPD and an output pad OPD. Each of the input pad IPD and the output pad OPD can be provided as a plurality of pads.

Each of the plurality of input pads IPD and the plurality of output pads OPD can be repeatedly disposed in the first direction DR1. The output pad OPD can be disposed at one side of the input pad IPD in the second direction DR2, and the input pad IPD can be disposed at the other side of the output pad OPD in the second direction DR2.

The input pad IPD and the output pad OPD can be electrically connected in contact with the data driving unit DIC mounted on the first pad area PA1. The input pad IPD can be electrically connected in contact with an input bump of the data driving unit DIC. The output pad OPD can be electrically connected in contact with an output bump of the data driving unit DIC.

The input pad IPD can receive various signals and voltages from the outside and transmit the signals and the voltages to the data driving unit DIC. The output pad OPD can supply various signals and voltages processed and output by the data driving unit DIC to the outside.

The second pad area PA2 can include a low-potential voltage pad VSSP, a high-potential voltage pad VDDP, a touch pad TPD, and a signal pad PD. The display panel 100 can be electrically connected to the printed circuit board FPCB through the second pad area PA2.

The low-potential voltage pad VSSP, the high-potential voltage pad VDDP, the touch pad TPD, and the signal pad PD can be disposed on the sixth insulating layer 109 and formed in multiple layers. The plurality of layers can include the same material as the first drain electrode 124, the second source electrode 131, and the second drain electrode 134 or include the same material as the connection electrode 145.

For example, the touch pad TPD can be disposed on the sixth insulating layer 109 and can be composed of a first touch pad layer TPD1, and a second touch pad layer TPD2 disposed on the first touch pad layer TPD1. The first touch pad layer TPD1 can be disposed on the same layer as the first source electrode 121, the first drain electrode 124, the second source electrode 131, and the second drain electrode 134, can include the same material as the first source electrode 121, the first drain electrode 124, the second source electrode 131, and the second drain electrode 134, and can be formed by the same process as the first source electrode 121, the first drain electrode 124, the second source electrode 131, and the second drain electrode 134. The second touch pad layer TPD2 can include the same material as the connection electrode 145 and can be formed by the same process as the connection electrode 145.

The input pad IPD can be disposed on the sixth insulating layer 109 and can be composed of a first input pad layer IPD1, a second input pad layer IPD2 disposed on the first input pad layer IPD1, and a third input pad layer IPD3 disposed on the second input pad layer IPD2. The first input pad layer IPD1 can be disposed on the same layer as the first source electrode 121, the first drain electrode 124, the second source electrode 131, and the second drain electrode 134, can include the same material as the first source electrode 121, the first drain electrode 124, the second source electrode 131, and the second drain electrode 134, and can be formed by the same process as the first source electrode 121, the first drain electrode 124, the second source electrode 131, and the second drain electrode 134. The second input pad layer IPD2 can include the same material as the connection electrode 145 and can be formed by the same process as the connection electrode 145. The third input pad layer IPD3 can include the same material as the sensor electrode 185 of the touch part 180 and can be formed by the same process as the sensor electrode 185 of the touch part 180.

The second input pad layer IPD2 and the third input pad layer IPD3 come into direct contact with each other, and in some areas, the touch buffer layer 181 and the first touch insulating layer 183 can be disposed between the second input pad layer IPD2 and the third input pad layer IPD3, but the embodiments of the present disclosure are not limited thereto.

The output pad OPD can be disposed on the sixth insulating layer 109 and can be composed of a first output pad layer OPD1, a second output pad layer OPD2 disposed on the first output pad layer OPD1, and a third output pad layer OPD3 disposed on the second output pad layer OPD2. The first output pad layer OPD1 can be disposed on the same layer as the first source electrode 121, the first drain electrode 124, the second source electrode 131, and the second drain electrode 134, can include the same material as the first source electrode 121, the first drain electrode 124, the second source electrode 131, and the second drain electrode 134, and can be formed by the same process as the first source electrode 121, the first drain electrode 124, the second source electrode 131, and the second drain electrode 134. The second output pad layer OPD2 can include the same material as the connection electrode 145 and can be formed by the same process as the connection electrode 145. The third output pad layer OPD3 can include the same material as the sensor electrode 185 of the touch part 180 and can be formed by the same process as the sensor electrode 185 of the touch part 180.

The second output pad layer OPD2 and the third output pad layer OPD3 come into direct contact with each other, and in some areas, the touch buffer layer 181 and the first touch insulating layer 183 can be disposed between the second output pad layer OPD2 and the third output pad layer OPD3, but the embodiments of the present disclosure are not limited thereto.

The second protective layer 112 can also be disposed in the sub-region SR. In the sub-region SR, the second protective layer 112 can expose the first pad area PA1 and the second pad area PA2. In the sub-region SR, the second protective layer 112 can expose the pads IPD and OPD disposed in the first pad area PA1 and the pads VSSP, VDDP, TPD, and PD disposed in the second pad area PA2.

In the sub-region SR, the second protective layer 112 can be disposed to be spaced apart from the pads IPD, OPD, VSSP, VDDP, TPD, and PD. In the sub-region SR, the second protective layer 112 can expose all regions of the pads IPD, OPD, VSSP, VDDP, TPD, and PD.

Since the second protective layer 112 is disposed to be spaced apart from the pads IPD, OPD, VSSP, VDDP, TPD, and PD, it is possible to block the moisture penetration path along which moisture, etc. can penetrate the pads IPD, OPD, VSSP, VDDP, TPD, and PD. Accordingly, it is possible to suppress or prevent moisture, etc. from penetrating the pads IPD, OPD, VSSP, VDDP, TPD, and PD and minimize bulging of the organic film, etc. Furthermore, it is possible to improve the reliability of the display panel 100, thereby increasing the life of the display apparatus 10 and reducing power consumption.

In the first pad area PA1, the second protective layer 112 can expose both the input pad IPD and the output pad OPD and can be disposed between the input pad IPD and the output pad OPD. The second protective layer 112 disposed on the first pad area PA1 can be formed in an island shape and disposed to be spaced apart from another second protective layers 112. However, the embodiments of the present disclosure are not limited thereto, and the second protective layer 112 disposed on the first pad area PA1 can be omitted.

The display apparatus 10 can include an input connection line ICL, an output connection line OCL, the low-potential voltage line VSSL, the high-potential voltage line VDDL, and a touch sensing line TSL, which are disposed on the display panel 100.

The input connection line ICL can be disposed between the signal pad PD and the input pad IPD and can electrically connect the signal pad PD to the input pad IPD. One side of the input connection line ICL can be electrically connected in contact with the signal pad PD, and the other side can be electrically connected in contact with the input pad IPD.

The input connection line ICL can be formed integrally with the input pad IPD, but is not limited thereto. The input connection line ICL can be formed of a first input connection line layer ICL1, and a second input connection line layer ICL2 disposed on the first input connection line layer ICL1. The first input connection line layer ICL1 can be formed integrally with the first input pad layer IPD1, and the second input connection line layer ICL2 can be formed integrally with the second input pad layer IPD2.

The output connection line OCL can be electrically connected in contact with the output pad OPD. One side of the output connection line OCL can be electrically connected to the output pad OPD, and the other side can be electrically connected to one selected from the data line, the gate line, etc.

The output connection line OCL can be formed integrally with the output pad OPD, but is not limited thereto. The output connection line OCL can be formed of a first output connection line layer OCL1, and a second output connection line layer OCL2 disposed on the first output connection line layer OCL1. The first output connection line layer OCL1 can be formed integrally with the first output pad layer OPD1. The second output connection line layer OCL2 can be formed integrally with the second output pad layer OPD2.

FIG. 7 illustrates that the signal pad PD is separated from the low-potential voltage pad VSSP, the high-potential voltage pad VDDP, and the touch pad TPD, and the low-potential voltage line VSSL, the high-potential voltage line VDDL, and the touch sensing line TSL are disposed independently of the first pad area PA1, but the embodiments of the present disclosure are not limited thereto.

For example, at least one of the low-potential voltage pad VSSP, the high-potential voltage pad VDDP, and the touch pad TPD can be one of the signal pads PD. For example, FIG. 7 illustrates that the low-potential voltage pad VSSP, the high-potential voltage pad VDDP, and the touch pad TPD are configured separately from the data driving unit DIC through separate lines VSSL, VDDL, and TSL, but at least one of the low-potential voltage pad VSSP, the high-potential voltage pad VDDP, and the touch pad TPD can be electrically connected to the input pad IPD through an input connection line ICL.

The low-potential voltage line VSSL can be electrically connected in contact with the low-potential voltage pad VSSP. The low-potential voltage line VSSL and the low-potential voltage pad VSSP can be formed integrally, but are not limited thereto, and can come into contact with each other through a contact hole, etc.

The high-potential voltage line VDDL can be electrically connected in contact with the high-potential voltage pad VDDP. The high-potential voltage line VDDL and the high-potential voltage pad VDDP can be formed integrally, but are not limited thereto, and can come into contact with each other through a contact hole, etc.

The touch sensing line TSL can be electrically connected in contact with the touch pad TPD. The touch sensing line TSL can include the same material as the sensor electrode 185 of the touch part 180. The touch sensing line TSL can be formed by the same process as the sensor electrode 185 of the touch part 180.

The touch sensing line TSL can be electrically connected in physical contact with the touch pad TPD exposed by the second protective layer 112, the touch buffer layer 181, and the first touch insulating layer 183. The touch sensing line TSL can have one side electrically connected to the touch pad TPD and the other side electrically connected to the sensor electrode 185 of the touch part 180.

The display apparatus 10 can include an over-etched area OE disposed on the substrate 101 in the sub-region SR. The over-etched area OE can be disposed in the non-display area NDA. The over-etched area OE can be disposed at one side of the touch pad TPD in the second direction DR2. The over-etched area OE can be disposed between the touch pad TPD and the display area DA. The over-etched area OE can be disposed between the bending region BR and the touch pad TPD. The over-etched area OE can be disposed between the second protective layer 112 disposed in the sub-region SR and the touch pad TPD.

In the over-etched area OE, at least parts of the panel insulating layers 102, 103, 104, 105-1, 105-2, 106, 107, 108, and 109 disposed between the substrate 101 and the touch pad TPD. The over-etched area OE can include a groove GR defined by the panel insulating layers 102, 103, 104, 105-1, 105-2, 106, 107, 108, and 109. For example, in the over-etched area OE, a sixth insulating layer 109 among the panel insulating layers 102, 103, 104, 105-1, 105-2, 106, 107, 108, and 109 can be recessed to expose a fifth insulating layer 108 thereunder. The groove GR defined by the sixth insulating layer 109 and the fifth insulating layer 108 can be disposed in the over-etched area OE.

In the groove GR, the touch buffer layer 181 can come into direct contact with the fifth insulating layer 108, but is not limited thereto.

In the over-etched area OE, the panel insulating layer disposed between the substrate 101 and the touch pad TPD can have a smaller thickness than the remaining area.

In the over-etched area OE, the panel insulating layer disposed between the substrate 101 and the touch pad TPD can have a lower height than the remaining area. Here, the height of the panel insulating layer can refer to a height of a top surface of the panel insulating layer from the substrate 101.

The over-etched area OE can overlap the touch sensing line TSL in the thickness direction (the third direction DR3). The touch sensing line TSL can extend across the over-etched area OE, but is not limited thereto.

The over-etched area OE can be formed during a process of etching the second protective layer 112 around the pads IPD, OPD, VSSP, VDDP, TPD, and PD.

Hereinafter, a manufacturing method of the present disclosure will be described. For contents that are substantially the same as those described with reference to FIGS. 1 to 9 among components included in the manufacturing method, the same reference numerals are given, and the overlapping contents can be omitted or briefly described.

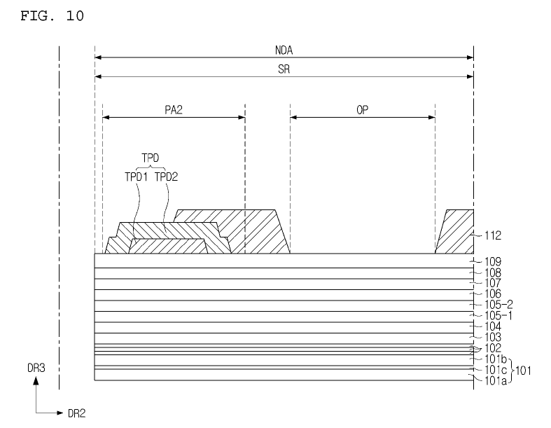

FIGS. 10 to 12 are views illustrating a manufacturing method for each process operation of the display apparatus according to the embodiment of the present disclosure. Particularly, FIGS. 10 to 12 illustrate cross sections of the second pad area PA2 of the sub-region SR.

First, referring to FIGS. 3 and 10, during the process of applying the second protective layer 112, the second protective layer 112 can also be disposed in the sub-region SR. The second protective layer 112 disposed in the sub-region SR can cover one side surface of the touch pad TPD in the second direction DR2. However, the embodiments of the present disclosure are not limited thereto, and the second protective layer 112 can cover one side surfaces of the pads IPD, OPD, VSSP, VDDP, TPD, and PD (see FIG. 7) in the second direction DR2.

Since the one side surfaces of the pads IPD, OPD, VSSP, VDDP, TPD, and PD (see FIG. 7) in the second direction DR2 are covered by the second protective layer 112, it is possible to suppress or prevent an etchant for patterning the first electrode 151 from being in contact with the pads IPD, OPD, VSSP, VDDP, TPD, and PD (see FIG. 7). In particular, when the pads IPD, OPD, VSSP, VDDP, TPD, and PD (see FIG. 7) include aluminum (Al), it is possible to suppress or prevent an Ag residue defect that can occur when the pads meet the silver (Ag) included in the etchant for patterning the first electrode 151 and further, suppress or prevent bulging of the second protective layer 112.

The second protective layer 112 can define an opening OP that exposes the panel insulation layer thereunder. The opening OP can expose the sixth insulation layer 109. The opening OP can be formed through patterning during the process of applying the second protective layer 112. Accordingly, a sidewall defining the opening OP can be formed to have a gentle taper.

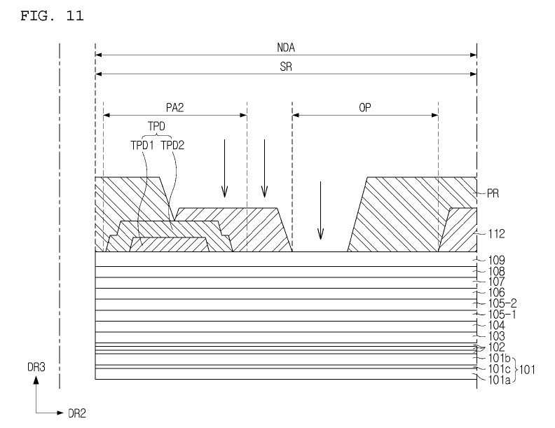

Referring further to FIG. 11, a photoresist PR that covers the second protective layer 112 at one side of the opening OP in the second direction DR2 and exposes the second protective layer 112 that is disposed at the other side in the second direction DR2 and covers the pads IPD, OPD, VSSP, VDDP, TPD, and PD (see FIG. 7) can be formed.

The photoresist PR can be patterned to expose the second protective layer 112 covering the pads IPD, OPD, VSSP, VDDP, TPD, and PD (see FIG. 7) and expose a part of the sixth insulating layer 109 exposed by the opening OP between the touch pad TPD and the second protective layer 112.

In FIG. 11, an exposed area that is not covered by the second protective layer 112 and the photoresist PR can correspond to the over-etched area OE of FIG. 7.

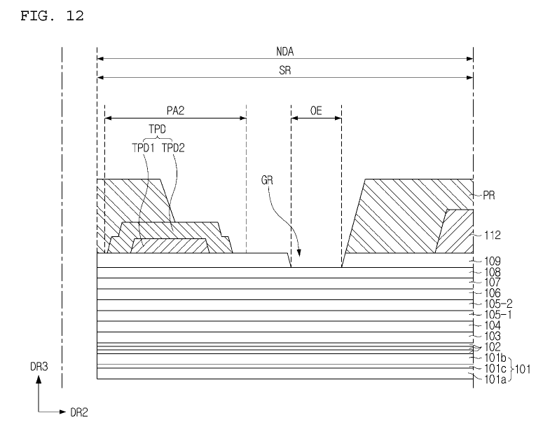

Referring further to FIG. 12, the area exposed by the photoresist PR can be etched. Since the second protective layer 112 covering the pads IPD, OPD, VSSP, VDDP, TPD, and PD (see FIG. 7) is removed, the pads IPD, OPD, VSSP, VDDP, TPD, and PD (see FIG. 7) can be disposed to be spaced apart from the second protective layer 112. Accordingly, it is possible to block the moisture penetration path along which moisture, etc. can penetrate the pads IPD, OPD, VSSP, VDDP, TPD, and PD.

In addition, in the area exposed by the photoresist PR, at least parts of the panel insulating layers 102, 103, 104, 105-1, 105-2, 106, 107, 108, and 109 disposed between the substrate 101 and the touch pad TPD can be etched in the thickness direction (the third direction DR3). In FIG. 12, the sixth insulating layer 109 exposed by the photoresist PR can be etched to form the over-etched area OE and the groove GR exposed by the fifth insulating layer 108.

When the opening OP of the second protective layer 112 is not formed and the same etching is performed by the photoresist PR, dry etching is performed, and after the etching, a side surface of the second protective layer 112 can be formed to have a taper with a large angle with the sixth insulating layer 109. For example, the side surface of the second protective layer 112 can have a very steep slope.

When the side surface of the second protective layer 112 has a steep slope, the touch sensing line TSL (see FIG. 8) may not be smoothly extended by a step coverage and can be disconnected during a deposition process.

For example, by forming the opening OP in advance during the process of patterning the second protective layer 112 so that the side surface of the second protective layer 112 has a gentle slope, the touch sensing line TSL (see FIG. 8) can be smoothly deposited.

The over-etched area OE and the groove GR can be formed during the manufacturing process of blocking the moisture penetration path along which moisture, etc. can penetrate the pads IPD, OPD, VSSP, VDDP, TPD, and PD and smoothly depositing the touch sensing line TSL (see FIG. 8).

Here, the photoresist PR can be a photoresist PR for forming the sensor holes SH1 and SH2 (see FIG. 1). For example, the process of removing the second protective layer 112 covering the pads IPD, OPD, VSSP, VDDP, TPD, and PD (see FIG. 7) and the process of forming the over-etched area OE and the groove GR can be performed by the same process as the process of forming the sensor holes SH1 and SH2 (see FIG. 1).

Accordingly, since a separate process is unnecessary, it is possible to minimize an increase in the time, cost, etc. used for the process.

Hereinafter, other embodiments of the present disclosure will be described. For contents that are substantially the same as those described with reference to FIGS. 1 to 12 among components included in other embodiments, the same reference numerals are given, and the overlapping contents can be omitted or briefly described.

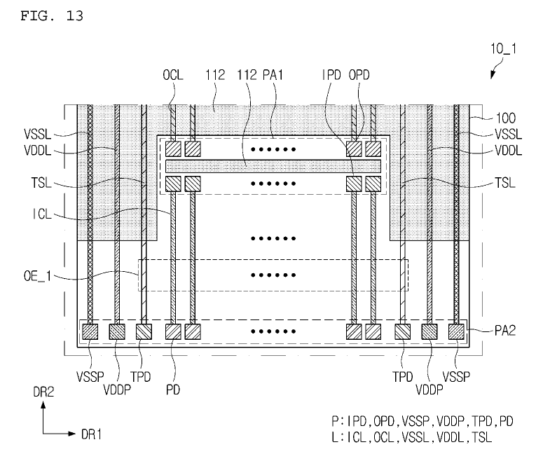

FIG. 13 is a plan view of a display panel according to another embodiment of the present disclosure. Particularly, FIG. 13 is an enlarged view of the sub-region SR of the display panel 100.

Referring to FIG. 13, an over-etched area OE_1 of a display apparatus 10_1 according to the present embodiment can overlap both the touch sensing line TSL and the input connection line ICL. The over-etched area OE_1 can extend in the first direction DR1 and intersect both the touch sensing line TSL and the input connection line ICL.

In this case, the embodiments of the present disclosure are not limited thereto, the input connection line ICL can include the same material as the sensor electrode 185 of the touch part 180 and can be formed by the same process as the sensor electrode 185 of the touch part 180.

FIG. 13 illustrates that the over-etched area OE_1 overlaps the touch sensing line TSL and the input connection line ICL, but the embodiments of the present disclosure are not limited thereto. For example, the over-etched area OE_1 can further extend in the first direction DR1 to overlap the low-potential voltage line VSSL and the high-potential voltage line VDDL.

FIG. 13 illustrates that the over-etched area OE_1 is formed integrally, but the embodiments of the present disclosure are not limited thereto. For example, the over-etched area OE_1 can be provided as a plurality of over-etched areas, and the plurality of over-etched areas OE_1 can be separated. In this case, the plurality of over-etched areas OE_1 can be disposed to overlap at least one of the plurality of touch sensing lines TSL and the plurality of input connection lines ICL.

For example, each of the plurality of over-etched areas OE_1 can overlap one touch sensing line TSL or one input connection line ICL.

In this case, since the second protective layer 112 is disposed to be spaced apart from the pads IPD, OPD, VSSP, VDDP, TPD, and PD, it is possible to block the moisture penetration path along which moisture, etc. can penetrate the pads IPD, OPD, VSSP, VDDP, TPD, and PD and smoothly deposit the touch sensing line TSL.

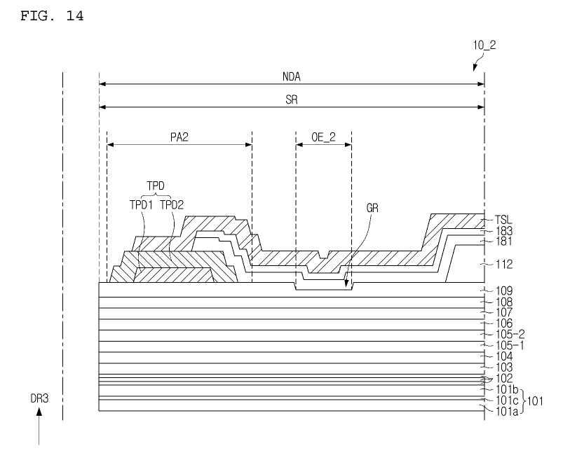

FIG. 14 is a cross-sectional view of a display apparatus according to still another embodiment of the present disclosure.

Referring to FIG. 14, an over-etched area OE_2 of a display apparatus 10_2 according to the present embodiment can be recessed in the thickness direction (the third direction DR3), but may not expose the fifth insulating layer 108.

Specifically, in the over-etched area OE_2, the sixth insulating layer 109 can be recessed in the thickness direction (the third direction DR3), but may not expose the fifth insulating layer 108. The side and lower surfaces of the groove GR can all be defined by the sixth insulating layer 109.

The lower surface of the groove GR can have different toughness from an upper surface of the sixth insulating layer 109 outside the over-etched area OE_2. The lower surface of the groove GR can have higher toughness than that the upper surface of the sixth insulating layer 109 outside the over-etched area OE_2, but is not limited thereto.

In this case, since the second protective layer 112 is disposed to be spaced apart from the pads IPD, OPD, VSSP, VDDP, TPD, and PD, it is possible to block the moisture penetration path along which moisture, etc. can penetrate the pads IPD, OPD, VSSP, VDDP, TPD, and PD and smoothly deposit the touch sensing line TSL.

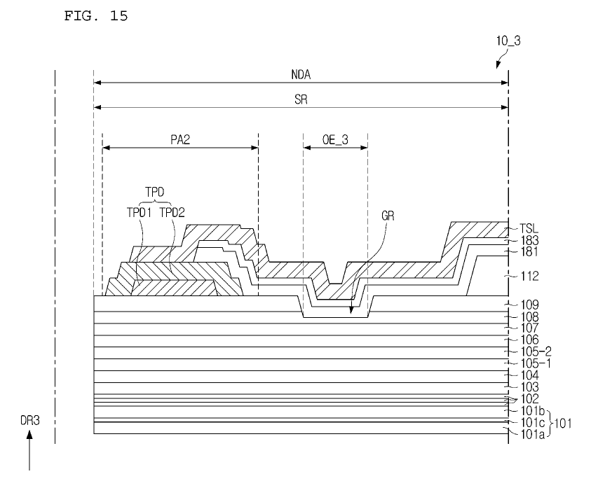

FIG. 15 is a cross-sectional view of a display apparatus according to yet another embodiment of the present disclosure.

Referring to FIG. 15, in an over-etched area OE_3 of a display apparatus 10_3 according to the present embodiment, the sixth insulating layer 109 and the fifth insulating layer 108 can also be recessed.

In the over-etched area OE_3, the sixth insulating layer 109 can penetrate in the thickness direction, and a part of the fifth insulating layer 108 can be recessed. Accordingly, the groove GR can be defined by the sixth insulating layer 109 and the fifth insulating layer 108. A lower surface of the groove GR can be defined by the fifth insulating layer 108, and a side surface of the groove GR can be defined by the sixth insulating layer 109 and the fifth insulating layer 108.

In this case, since the second protective layer 112 is disposed to be spaced apart from the pads IPD, OPD, VSSP, VDDP, TPD, and PD, it is possible to block the moisture penetration path along which moisture, etc. can penetrate the pads IPD, OPD, VSSP, VDDP, TPD, and PD and smoothly deposit the touch sensing line TSL.

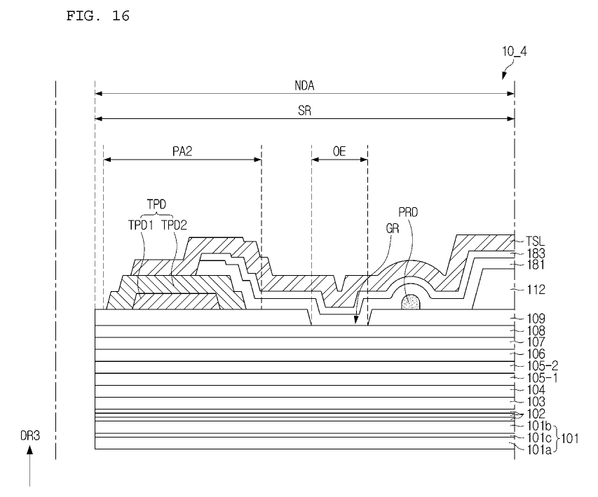

FIG. 16 is a cross-sectional view of a display apparatus according to yet another embodiment of the present disclosure.

Referring to FIG. 16, a display apparatus 10_4 according to the present embodiment further includes a photoresist residue PRD. The photoresist residue PRD can be a residue that remains after the photoresist PR of FIG. 11 is not removed.

The photoresist residue PRD can be disposed between the second protective layer 112 and the over-etched area OE. The photoresist residue PRD can be disposed between the sixth insulating layer 109 and the touch buffer layer 181.

In this case, since the second protective layer 112 is disposed to be spaced apart from the pads IPD, OPD, VSSP, VDDP, TPD, and PD, it is possible to block the moisture penetration path along which moisture, etc. can penetrate the pads IPD, OPD, VSSP, VDDP, TPD, and PD and smoothly deposit the touch sensing line TSL.

A display apparatus according to various embodiments of the present disclosure can be described as follows.

According to embodiments of the present disclosure, there is provided a display apparatus including a substrate, a panel insulating layer disposed on the substrate and including a plurality of insulating layers, a touch pad disposed on the panel insulating layer, a protective layer disposed to be spaced apart from the touch pad on the panel insulating layer and including an organic material, and an over-etched area which is disposed between the touch pad and the protective layer and in which at least a part of the panel insulating layer is recessed.

According to various embodiments of the present disclosure, the display apparatus can further include a main region including a display area, a sub-region, and a bending region disposed between the main region and the sub-region, in which the touch pad, the protective layer, and the over-etched area can be disposed in the sub-region.

According to various embodiments of the present disclosure, the display apparatus can further include a non-display area disposed around the display area, in which the touch pad, the protective layer, and the over-etched area can be disposed in the non-display area.

According to various embodiments of the present disclosure, the display apparatus can further include a touch sensing line electrically connected to the touch pad, in which the touch sensing line can overlap the over-etched area.

According to various embodiments of the present disclosure, the display apparatus can further include a first pad area including a plurality of input pads and a plurality of output pads, a second pad area including a touch pad and a plurality of signal pads, and a plurality of input connection lines electrically connecting the plurality of input pads to the plurality of signal pads, in which the plurality of input connection lines can overlap the over-etched area.

According to various embodiments of the present disclosure, the touch sensing line can extend to be spaced apart from the first pad area.

According to various embodiments of the present disclosure, the display apparatus can further include a light-emitting part disposed on the protective layer, and a touch part disposed on the light-emitting part, in which the touch part can include a sensor electrode and a bridge electrode connecting the sensor electrode, and the touch sensing line can include the same material as the sensor electrode.

According to various embodiments of the present disclosure, the display apparatus can further include a second pad area in which the touch pad is disposed, and a printed circuit board mounted on the second pad area.

According to various embodiments of the present disclosure, the display apparatus can further include a first pad area including an input pad and an output pad, and a data driving unit mounted on the first pad area.

According to various embodiments of the present disclosure, a protective layer can be disposed in an island shape between the input pad and the output pad.

According to various embodiments of the present disclosure, the protective layer can expose an entire area of the touch pad.

According to various embodiments of the present disclosure, the panel insulating layer can include a first insulating layer and a second insulating layer disposed on the first insulating layer, and in the over-etched area, the second insulating layer can be penetrated in a thickness direction to expose the first insulating layer.

According to various embodiments of the present disclosure, a part of an upper portion of the first insulating layer exposed by the second insulating layer can be recessed.

According to various embodiments of the present disclosure, the panel insulating layer can include a first insulating layer and a second insulating layer disposed on the first insulating layer, and in the over-etched area, the second insulating layer can cover the first insulating layer.

According to various embodiments of the present disclosure, the panel insulating layer can further include a photoresist residue disposed on the panel insulating layer, in which the photoresist residue can be disposed between the protective layer and the over-etched area.

According to embodiments of the present disclosure, there is provided a display apparatus including a substrate, a panel insulating layer disposed on the substrate and including a plurality of insulating layers, a pad disposed on the panel insulating layer, a connection line electrically connected to the pad, and an over-etched area in which at least a part of the panel insulating layer is recessed, in which the over-etched area can overlap a connection line.

According to various embodiments of the present disclosure, the pad can be a touch pad, and the connection line can be a touch sensing line electrically connected to the touch pad.

According to various embodiments of the present disclosure, the display apparatus can further include a protective layer disposed on the panel insulating layer, in which the over-etched area can be disposed between the pad and the protective layer.

According to various embodiments of the present disclosure, the display apparatus can further include a main region including a display area, a sub-region, and a bending region disposed between the main region and the sub-region, in which the pad, the protective layer, and the over-etched area can be disposed in the sub-region.

According to various embodiments of the present disclosure, the protective layer can expose an entire area of the pad.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

10: display apparatus

100: display panel

101: substrate

120, 130: thin film transistor

111: first protective layer

112: second protective layer

150: light-emitting part

151: first electrode

ANO: anode electrode

152: organic layer

153: second electrode

PA1: first pad area

PA2: second pad area

TPD: touch pad

TSL: touch sensing line

OE: over-etched area

GR: groove

1. A display apparatus comprising:
a substrate;
a panel insulating layer disposed on the substrate and including a plurality of insulating layers;
a touch pad disposed on the panel insulating layer;
a protective layer disposed to be spaced apart from the touch pad on the panel insulating layer, and including an organic material; and
an over-etched area disposed between the touch pad and the protective layer,
wherein at least a part of the panel insulating layer is recessed in the over-etched area.

2. The display apparatus of claim 1, further comprising a main region including a display area, a sub-region, and a bending region disposed between the main region and the sub-region,
wherein the touch pad, the protective layer, and the over-etched area are disposed in the sub-region.

3. The display apparatus of claim 2, further comprising a non-display area disposed around the display area,
wherein the touch pad, the protective layer, and the over-etched area are disposed in the non-display area.

4. The display apparatus of claim 1, further comprising a touch sensing line electrically connected to the touch pad,
wherein the touch sensing line overlaps the over-etched area.

5. The display apparatus of claim 4, further comprising:
a first pad area including a plurality of input pads and a plurality of output pads;
a second pad area including the touch pad and a plurality of signal pads; and
a plurality of input connection pads electrically connecting the plurality of input pads to the plurality of signal pads,
wherein the plurality of input connection lines overlap the over-etched area.

6. The display apparatus of claim 5, wherein the touch sensing line extends to be spaced apart from the first pad area.

7. The display apparatus of claim 4, further comprising:
a light-emitting part disposed on the protective layer; and
a touch part disposed on the light-emitting part,
wherein the touch part includes a sensor electrode and a bridge electrode connecting the sensor electrode, and
wherein the touch sensing line includes a same material as the sensor electrode.

8. The display apparatus of claim 1, further comprising:
a second pad area in which the touch pad is disposed; and
a printed circuit board mounted on the second pad area.

9. The display apparatus of claim 8, further comprising:
a first pad area including an input pad and an output pad; and
a data driving unit mounted on the first pad area.

10. The display apparatus of claim 9, wherein the protective layer is disposed in an island shape between the input pad and the output pad.

11. The display apparatus of claim 1, wherein the protective layer exposes an entire area of the touch pad.

12. The display apparatus of claim 1, wherein the panel insulating layer includes a first insulating layer, and a second insulating layer disposed on the first insulating layer, and
wherein in the over-etched area, the second insulating layer is penetrated in a thickness direction to expose the first insulating layer.

13. The display apparatus of claim 12, wherein a part of an upper portion of the first insulating layer exposed by the second insulating layer is recessed.

14. The display apparatus of claim 1, wherein the panel insulating layer includes a first insulating layer, and a second insulating layer disposed on the first insulating layer, and
wherein in the over-etched area, the second insulating layer covers the first insulating layer.

15. The display apparatus of claim 1, further comprising a photoresist residue disposed on the panel insulating layer,
wherein the photoresist residue is disposed between the protective layer and the over-etched area.

16. A display apparatus comprising:
a substrate;
a panel insulating layer disposed on the substrate and including a plurality of insulating layers;
a pad disposed on the panel insulating layer;
a connection line electrically connected to the pad; and
an over-etched area in which at least a part of the panel insulating layer is recessed,
wherein the over-etched area overlaps the connection line.

17. The display apparatus of claim 16, wherein the pad is a touch pad, and the connection line is a touch sensing line electrically connected to the touch pad.

18. The display apparatus of claim 17, further comprising a protective layer disposed on the panel insulating layer,
wherein the over-etched area is disposed between the pad and the protective layer.

19. The display apparatus of claim 18, further comprising a main region including a display area, a sub-region, and a bending region disposed between the main region and the sub-region,
wherein the pad, the protective layer, and the over-etched area are disposed in the sub-region.

20. The display apparatus of claim 19, wherein the protective layer exposes an entire area of the pad.
